(19) United States
(12) Patent Application Publication
(10) Pub. No.: US 2026/0040893 A1
(43) Pub. Date: Feb. 5, 2026

(54) INSPECTION METHOD OF WAFER DICING PROCESS

(71) Applicant: OPXION TECHNOLOGY INC., New Taipei City (TW)

(72) Inventors: FENG-YU CHANG, New Taipei City (TW); MENG-TSAN TSAI, New Taipei City (TW); WEN-JU CHEN, New Taipei City (TW); MING-FENG WU, New Taipei City (TW); PO-HSU SU, New Taipei City (TW); CHENG-YU LU, New Taipei City (TW)

(73) Assignee: OPXION TECHNOLOGY INC., New Taipei City (TW)

(21) Appl. No.: 18/907,612

(22) Filed: Oct. 7, 2024

(30) Foreign Application Priority Data
Aug. 5, 2024 (TW) 113129167

(51) Int. Cl. H01L 21/66; G01N 21/95; H01L 21/78

(52) U.S. Cl. CPC H01L 22/12; G01N 21/9501; H01L 21/78

(57) ABSTRACT

A method of inspecting a wafer dicing process entails performing a scanning process on a grooved wafer with a light beam used by an optical scanning device. The method includes using a film layer of the grooved wafer as an incident surface for the scanning process; performing the scanning process on the grooved wafer in a Y-axis direction to obtain XZ section structure images corresponding in position to consecutive different Y-axis positions on the grooved wafer; analyzing the XZ section structure images at the consecutive different positions and defining positions corresponding in position to grooves, the film layer, a silicon layer and a metal layer; and analyzing a depth of each of the grooves to determine whether the grooved wafer is grooved successfully or grooved unsuccessfully. Therefore, the method is applicable to wafer processing procedures and addresses the lack of inspection methods in the wafer dicing process.

### CROSS-REFERENCE TO RELATED APPLICATION

This non-provisional application claims priority under 35 U.S.C. § 119 (a) on Patent Application No(s). 113129167 filed in Taiwan, R.O.C. on Aug. 5, 2024, the entire contents of which are hereby incorporated by reference.

### BACKGROUND OF THE INVENTION

### 1. Field of the Invention

The present disclosure relates to wafer inspection methods, and in particular to an inspection method of a wafer dicing process.

### 2. Description of the Related Art

During existing wafer processing, an integrated circuit is formed on a wafer comprising semiconductor materials (such as silicon), and then the wafer is processed to form a lot of self-contained regions, with the self-contained regions each including an integrated circuit known as a chip. Upon the formation of the integrated circuit on the wafer, a dicing process is performed on the wafer to separate the chips on the wafer from each other, allowing the chips to be ready for use in subsequent procedures, such as packaging.

During the dicing process, a scribing space is formed between the chips on the wafer by following a grooving step, a scribing step and a sawing step, and then the chips on the wafer are separated from each other along the scribing space. The scribing space is usually known as dicing streets.

In the grooving, scribing and sawing steps, it is possible for structural issues, such as cracks and/or fractures, to exist in the dicing streets and expand to the detriment of the quality of the chips and even damage the chips.

The aforesaid drawback occurs because the grooving, scribing and sawing steps are confronted with control-related problems, such as insufficient excitation energy of a laser beam for use in grooving, and incident angle shift, or control-related problems, such as inadequate dicing force strength of a dicing cutting tool, dicing angle shift, and worn-out cutting tools.

### BRIEF SUMMARY OF THE INVENTION

Since the conventional dicing process takes place continuously, the grooving step is followed by the scribing step and the sawing step. Therefore, it is only when the chip inspecting stage is taking place that a chip is found to be damaged because of the expansion of cracks and/or fractures in the dicing streets, leading to an increase in the undetected rate of defective wafers.

As a result, there is a lack of inspection methods in the conventional wafer dicing process, rendering it impossible to correct control parameters of a laser beam and a dicing cutting tool with a view to improving wafer yield upon completion of each of the grooving step, scribing step and sawing step.

To achieve the above and other objectives, the disclosure provides an inspection method of a wafer dicing process, adapted to perform a scanning process on a grooved wafer with a light beam used by an optical scanning device, the inspection method comprising the steps of: using an adhesive film layer or metal layer of the grooved wafer as a light incident surface for the scanning process; performing the scanning process on the grooved wafer in a Y-axis direction to obtain XZ section structure images corresponding in position to successive different Y-axis positions on the grooved wafer; analyzing the XZ section structure images at the successive different Y-axis positions and defining positions corresponding in position to a plurality of grooves, the adhesive film layer, a silicon layer and the metal layer; and analyzing a depth of each of the grooves to determine whether the grooved wafer is grooved successfully or grooved unsuccessfully.

In some embodiments, a determination that the depth of each of the grooves exceeds a border between the silicon layer and the metal layer causes a confirmation that the grooved wafer is grooved successfully, and a determination that the depth of each of the grooves is equal to or less than the border between the silicon layer and the metal layer causes a confirmation that the grooved wafer is grooved unsuccessfully.

In some embodiments, the inspection method further comprises, after the step of analyzing whether a depth of each of the grooves exceeds or is equal to the border between the silicon layer and the metal layer to determine whether the grooved wafer is grooved successfully or grooved unsuccessfully, the steps of: performing a dicing process on the grooved wafer to form a diced wafer; using the adhesive film layer or the metal layer of the diced wafer as a light incident surface for the scanning process; performing the scanning process on the diced wafer to obtain XZ section structure images corresponding in position to successive different Y-axis positions or YZ section structure images corresponding in position to successive different X-axis positions on the diced wafer; analyzing the XZ section structure images at the successive different Y-axis positions or the YZ section structure images at the successive different X-axis positions and defining positions corresponding in position to a plurality of dicing streets, the adhesive film layer, the silicon layer, the metal layer, and a sidewall chipping defect; calculating a maximum depth value according to a pixel length corresponding to a maximum depth of the sidewall chipping defect, and calculating a thickness value according to a thickness of the silicon layer; and calculating a sidewall chipping defect depth percentage according to the maximum depth value and the thickness value.

In some embodiments,

$$the sidewall chipping defect depth percentage = \frac{maximum depth value}{thickness value} \times 100 \% .$$

In some embodiments, the inspection method further comprises, after the step of analyzing the YZ section structure images at the successive different X-axis positions and defining positions corresponding in position to a plurality of dicing streets, the adhesive film layer, the silicon layer, the metal layer, and a sidewall chipping defect, the steps of: analyzing each of the dicing streets and recognizing positions corresponding in position to a dicing street width and a dicing street depth; and calculating a dicing street aspect ratio according to a width value corresponding to the dicing street width and a depth value corresponding to the dicing street depth.

In some embodiments,

$$the dicing street aspect ratio = \frac{depth value}{width value} .$$

In some embodiments, the inspection method further comprises, after the step of analyzing each of the dicing streets and recognizing positions corresponding in position to a dicing street width and a dicing street depth, the steps of: calculating a first dicing street perpendicularity according to a first width value corresponding to the dicing street width; calculating a second dicing street perpendicularity according to a second width value corresponding to the dicing street width; and calculating a dicing street inclination according to the first dicing street perpendicularity and the second dicing street perpendicularity.

In some embodiments, the inspection method further comprises the steps of: obtaining first end point XY coordinates corresponding to left edges of top-surface dicing streets of the silicon layer and second end point XY coordinates corresponding to right edges of top-surface dicing streets of the silicon layer according to XY section structure images of the silicon layer; obtaining third end point XY coordinates corresponding to left edges of bottom-surface dicing streets of the silicon layer and fourth end point XY coordinates corresponding to right edges of bottom-surface dicing streets of the silicon layer according to XY section structure images of the silicon layer; and subtracting the first end point XY coordinates and the third end point XY coordinates from each other to obtain left dicing street shift extent corresponding to the silicon layer, and subtracting the second end point XY coordinates and the fourth end point XY coordinates from each other to obtain right dicing street shift extent corresponding to the silicon layer.

In some embodiments, the inspection method further comprises, after the step of using the adhesive film layer or the metal layer of the diced wafer as a light incident surface for the scanning process, the steps of: performing the scanning process on the diced wafer in X-axis and Y-axis directions to obtain XY section structure images corresponding in position to successive different Z-axis positions (depth) on the diced wafer; analyzing XY section structure images at successive different Z-axis positions, defining positions corresponding in position to a defective region and a chip edge, and determining a position of a seal ring according to XY section structure images of the metal layer; and analyzing whether the defective region exceeds the seal ring to determine whether the diced wafer is a normal die or a defective die.

In some embodiments, a determination that the defective region exceeds the seal ring causes a confirmation that the diced wafer is a defective die, and a determination that the defective region does not exceed the seal ring causes a confirmation that the diced wafer is a normal die.

In some embodiments, the inspection method further comprises, after the step of analyzing XY section structure images at successive different Z-axis positions and defining positions corresponding in position to a defective region and a chip edge, the step of analyzing whether the defective region is located within the seal ring to determine whether the diced wafer is a normal die or a defective die. In conclusion, an inspection method of a wafer dicing process according to the disclosure is adapted to scan a grooved wafer or diced wafer with a light beam used by an optical scanning device to obtain optical signals and then perform conversion on the optical signals with an optical image processing device to display different section structure images corresponding to the grooved wafer or diced wafer to facilitate the observation of internal structures of dicing streets and thereby confirm the processing quality of the dicing streets.

### BRIEF DESCRIPTION OF THE DRAWINGS

FIG. 1 is a block diagram of an optical scanning system for scanning a grooved wafer according to an embodiment of the disclosure.

FIG. 2 is a schematic view of YZ section structure images and XZ section structure images according to an embodiment of the disclosure.

FIG. 3 is a schematic view of how to perform a grooving procedure and a scanning process on the grooved wafer according to an embodiment of the disclosure.

FIG. 4 is a partial XZ section structure images picture of the grooved wafer obtained upon completion of the scanning process performed on the grooved wafer according to an embodiment of the disclosure.

FIG. 5 is a schematic view of how to perform a dicing process and the scanning process on the grooved wafer according to an embodiment of the disclosure.

FIG. 6 is a partial structural schematic view of a diced wafer with a sidewall chipping defect according to an embodiment of the disclosure.

FIG. 7 is another partial structural schematic view of the diced wafer according to an embodiment of the disclosure.

FIG. 8 is yet another partial structural schematic view of the diced wafer according to an embodiment of the disclosure.

FIG. 9 is a structural schematic view of a metal layer of the diced wafer according to an embodiment of the disclosure.

FIG. 10 is a schematic view of a process flow of an inspection method of a wafer dicing process (grooved stage) according to an embodiment of the disclosure.

FIG. 11 is a schematic view of a process flow of the inspection method of a wafer dicing process (diced stage) according to another embodiment of the disclosure.

FIG. 12 is a schematic view of a process flow of the inspection method of a wafer dicing process according to yet another embodiment of the disclosure.

FIG. 13A is a schematic view of a process flow of the inspection method of a wafer dicing process according to still yet another embodiment of the disclosure.

FIG. 13B is a schematic view of a process flow of the inspection method of a wafer dicing process according to still yet another embodiment of the disclosure.

FIG. 14 is a schematic view of a process flow of the inspection method of a wafer dicing process according to still yet another embodiment of the disclosure.

### DETAILED DESCRIPTION OF THE INVENTION

In an embodiment of the disclosure, the expression “an optical signal” means a light beam, parallel light beams, a light beam of light beams, and a focused light beam. The light beam includes visible light and invisible light (such as near-infrared light), and the expression “successive different positions” means a target coordinate position and its neighboring coordinate positions in the same axial direction, such as X1, X2, X3, . . . , and so on of X axis; Y1, Y2, Y3, . . . , and so on of Y axis; and Z1, Z2, Z3, . . . , and so on of Z axis.

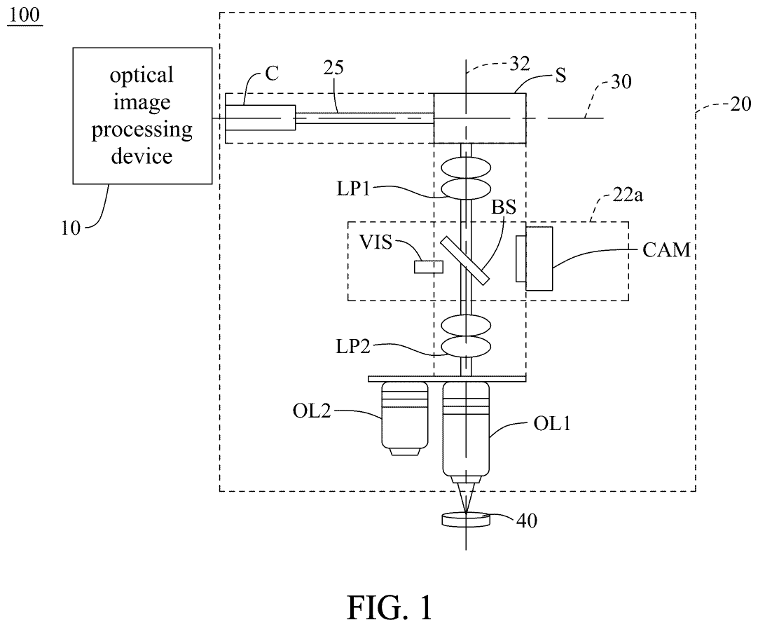

Referring to FIG. 1, there is shown a block diagram of an optical scanning system for scanning a grooved wafer 40 according to an embodiment of the disclosure. An optical scanning system 100 for scanning the grooved wafer 40 comprises an optical image processing device 10 and an optical scanning device 20. The optical image processing device 10 is configured to generate parallel light beams 25 traveling in a first optical axis direction 30. The optical image processing device 10 comprises a light beam source module, interferometer, spectrum analyzer, optical coherence tomography (OCT) machine, and host computer, but the disclosure is not limited thereto. In an embodiment of the disclosure, three-dimensional structure images of the grooved wafer 40 are obtained with the optical image processing device 10 and the optical scanning device 20. Since the three-dimensional structure images include fault images data, the three-dimensional structure images are used to check and confirm whether defects are present outside and inside the grooves of the grooved wafer 40, overcoming a drawback of the prior art—the prior art is incapable of inspecting dicing street structure.

The optical scanning device 20 is coupled to the optical image processing device 10. The optical scanning device 20 is configured to convert the light beams traveling in the first optical axis direction 30 into the light beams 25 traveling in a second optical axis direction 32 and scan the grooved wafer 40 with the light beams 25 traveling in the second optical axis direction 32. By the verb “convert”, it means changing the advancing direction of the light beams 25 from a first angle to a second angle, with the first angle exemplified by 0°, and the second angle exemplified by 90°. In this embodiment, the first optical axis direction 30 is substantially perpendicular to the second optical axis direction 32.

Optical signals generated as a result of reflection and/or scattering of the light beams 25 on the surface and inside of the grooved wafer 40 are received by first objective lens OL1 and take the original path to return to the optical image processing device 10 to undergo a processing procedure for converting signals to images. The original path is as follows: optical image processing device 10→collimator C→beam scanner S→first lens assembly LP1→beam splitter BS→second lens assembly LP2→first objective lens OL1. The returning path is as follows: first objective lens OL1→second lens assembly LP2→beam splitter BS→first lens assembly LP1→beam scanner S→collimator C→optical image processing device 10. In the other embodiments, when first objective lens OL1 is replaced by second objective lens OL2, second objective lens OL2 substitutes for first objective lens OL1 to follow the original path and the returning path.

The optical scanning device 20 comprises a collimator C, beam scanner S, first lens assembly LP1, visible-light camera module 22a, second lens assembly LP2, first objective lens OL1 and second objective lens OL2. In this embodiment, first objective lens OL1 and second objective lens OL2 together form an objective lens module. The magnifying power of the objective lens module is adjustable. For example, the magnifying power of the first objective lens OL1 is different from the magnifying power of the second objective lens OL2. The magnifying power of the first objective lens OL1 is greater than or less than the magnifying power of the second objective lens OL2. In the other embodiments, the number of the objective lens in the objective lens module may be increased or decreased as needed.

The collimator C is configured to receive the light beams 25 generated from the optical image processing device 10 and traveling in the first optical axis direction 30 and convert the light beams 25 into the light beams 25 parallel to the first optical axis direction 30. The term “convert” means that the light beams 25 are converged to become the light beams 25 parallel to the first optical axis direction 30.

The beam scanner S is disposed at the junction of the first optical axis direction 30 and the second optical axis direction 32. The beam scanner S is configured to receive the light beams 25 passing through the collimator C and being parallel to the first optical axis direction 30 and convert the light beams 25 parallel to the first optical axis direction 30 into the light beams 25 parallel to the second optical axis direction 32.

The first lens assembly LP1 is disposed in the second optical axis direction 32. The first lens assembly LP1 is configured to expand or contract the light beams parallel to the second optical axis direction 32. In this embodiment, the first lens assembly LP1 is configured to expand the light beams 25 parallel to the second optical axis direction 32.

The visible-light camera module 22a is disposed proximal to the second optical axis direction 32, and the lens direction of the visible-light camera module 22a is perpendicular to the second optical axis direction 32. The visible-light camera module 22a is configured to capture two-dimensional (XY) surface images of an adhesive film layer 42 of the grooved wafer 40.

The visible-light camera module 22a comprises a camera CAM, visible light source VIS, and beam splitter BS. The beam splitter BS is disposed in the second optical axis direction 32. The camera CAM and the visible light source VIS are disposed on the two opposing sides of the beam splitter BS respectively. More specifically, the camera CAM is disposed on the right side of the second optical axis direction 32. The visible light source VIS is disposed on the left side of the second optical axis direction 32.

The operation of the visible-light camera module 22a is described below. The visible light generated from the visible light source VIS is rotated by 90° through the beam splitter BS before being incident on the second lens assembly LP2. After exiting the second lens assembly LP2, the visible light is focused by the first objective lens OL1 onto the grooved wafer 40. After reflecting off the grooved wafer 40, the visible light is rotated by 90° through the beam splitter BS to enter the camera CAM for imaging, and thus the two-dimensional (XY) surface images of the adhesive film layer 42 of the grooved wafer 40 can be captured. Therefore, the optical scanning device 20 uses the visible-light camera module 22a to directly capture the two-dimensional (XY) surface images of the adhesive film layer 42 of the grooved wafer 40 and inspect the two-dimensional (XY) images for the surface state of the adhesive film layer 42 of the wafer so as to confirm scanning wafer position and surface state.

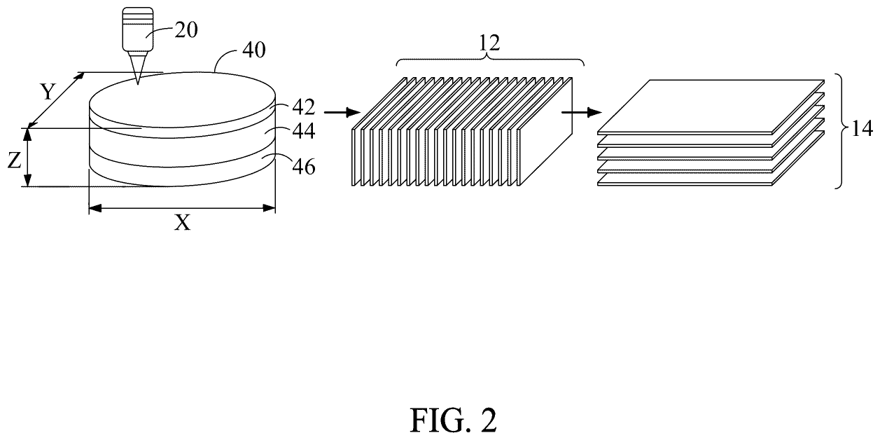

Referring to FIG. 2, there is shown a schematic view of YZ section structure images and XZ section structure images according to an embodiment of the disclosure.

The optical scanning device 20 scans the grooved wafer 40 in X-axis direction to obtain a corresponding optical signal. The optical scanning device 20 uses a driving device (not shown) to perform the scanning operation in X-axis direction. The driving device is, for example, a linear motor, but the disclosure is not limited thereto. The optical signal is transmitted by the optical scanning device to the optical image processing device 10 to undergo signal-to-image conversion to obtain YZ section structure images 12 corresponding in position to successive different X-axis positions on the grooved wafer 40.

Likewise, the optical scanning device 20 scans the grooved wafer 40 in Y-axis direction to obtain a corresponding optical signal. The optical scanning device uses a driving device to perform scanning operation in Y-axis direction. The optical signal is transmitted by the optical scanning device 20 to the optical image processing device 10 to undergo signal-to-image conversion to obtain XZ section structure images (FIG. 2 omits XZ section structure images for the sake of simplifying the diagram) corresponding in position to successive different Y-axis positions on the grooved wafer 40.

The optical image processing device 10 combines YZ section structure images at successive different positions and XZ section structure images at successive different positions to form XY section structure images 14 at successive different positions. The optical image processing device 10 reconstructs three-dimensional structure images corresponding to the grooved wafer 40. The three-dimensional structure images include but are not limited to YZ section structure images at successive different X-axis positions, XZ section structure images at successive different Y-axis positions, and XY section structure images 14 at successive different Z-axis positions.

Furthermore, the optical scanning device 20 scans the grooved wafer 40 to obtain optical signals in Z-axis direction and thus dispenses with the need to use any driving device to change the position of the optical scanning device 20 in Z-axis direction, enhancing the ease of inspection of the grooved wafer 40 and reducing the time taken to scan the grooved wafer 40.

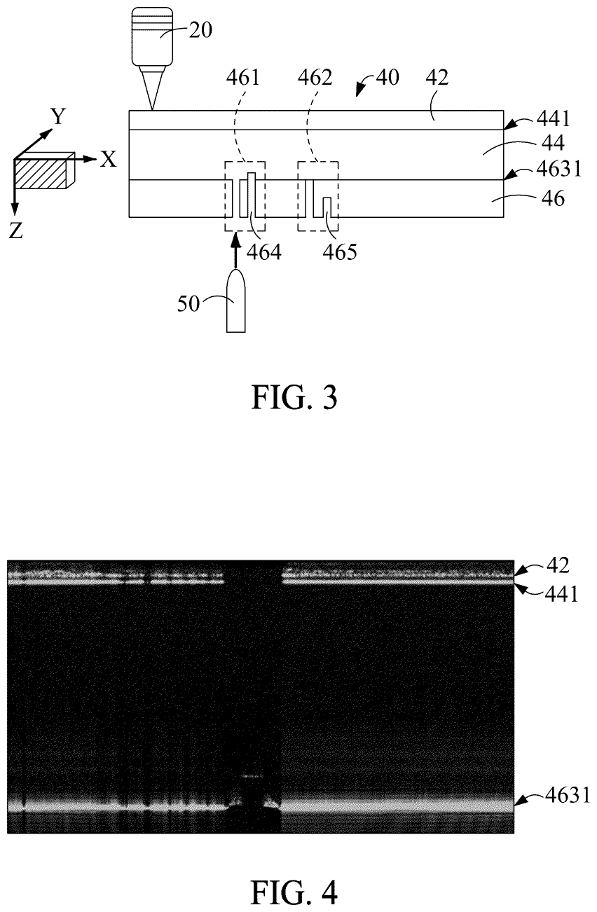

Refer to FIG. 3 and FIG. 4. FIG. 3 is a schematic view of how to perform a grooving procedure and a scanning process on the grooved wafer 40 according to an embodiment of the disclosure. FIG. 4 is a partial XZ section structure images picture of the grooved wafer 40 obtained upon completion of the scanning process performed on the grooved wafer 40 according to an embodiment of the disclosure. As shown in FIG. 3, the optical scanning device 20 and a laser head 50 are disposed on different sides of the grooved wafer 40 respectively. The optical scanning device is disposed on one side of the adhesive film layer 42 of the grooved wafer 40, and the laser head 50 is disposed on one side of a metal layer 46 of the grooved wafer 40. The optical scanning device 20 uses the adhesive film layer 42 of the grooved wafer 40 as a light incident surface for the scanning process; it is because using the metal layer 46 of the grooved wafer 40 as a light incident surface for the scanning process may cause the reflection of a light beam and thus affect the obtained optical signals. In the other embodiments, the optical scanning device 20 may use the metal layer 46 of the grooved wafer 40 as a light incident surface for the scanning process.

Upon completion of the grooving procedure, a first dicing street region 461 and a second dicing street region 462 are formed on the grooved wafer 40. A groove 464 and a groove 465 are formed in the first dicing street region 461 and the second dicing street region 462 with a laser beam generated from the laser head 50 respectively.

The optical scanning device 20 performs the scanning process on the grooved wafer 40 to obtain XZ section structure images corresponding in position to successive different Y-axis positions on the grooved wafer 40. Referring to FIG. 4, there are shown partial XZ section structure images corresponding in position to the grooved wafer 40. The optical image processing device 10 analyzes XZ section structure images at successive different Y-axis positions and defines positions corresponding in position to a plurality of grooves (not denoted by any reference numerals in the diagram), the adhesive film layer 42, a silicon layer 44, and the metal layer 46. Owing to a difference in refractive indices between a physical matter and air, XZ section structure images show glittering stripes corresponding in position to the adhesive film layer 42, glittering stripes corresponding in position to silicon layer front side 441, and glittering stripes corresponding in position to metal layer back side 4631. Therefore, image features in XZ section structure images are analyzed with an image processing algorithm to locate the grooves, the adhesive film layer 42, the silicon layer 44, and the metal layer 46. Then, it is feasible to identify how the glittering stripes correlate with the adhesive film layer 42, the silicon layer 44 and the metal layer 46 according to the known actual thickness of the adhesive film layer 42, the silicon layer 44 and the metal layer 46 in the grooved wafer 40 and thereby define the positions of the adhesive film layer 42, the silicon layer 44, and the metal layer 46. Furthermore, truncated image features on the glittering stripes are analyzed and defined as the positions of the grooves. Therefore, the positions of the grooves, the adhesive film layer 42, the silicon layer 44, and the metal layer 46 are defined.

As shown in FIG. 3, the determination that the depth of each of the grooves exceeds the border between the silicon layer 44 and the metal layer 46 causes the confirmation that the grooved wafer 40 is grooved successfully. For instance, when the depth of the groove 464 in the first dicing street region 461 exceeds the border between the silicon layer 44 and the metal layer 46, it can be confirmed that the grooved wafer 40 is grooved successfully.

The determination that the depth of one of the grooves is equal to or less than the border between the silicon layer 44 and the metal layer 46 causes the confirmation that the grooved wafer 40 is grooved unsuccessfully. For instance, when the depth of the groove 465 in the second dicing street region 462 is less than the border between the silicon layer 44 and the metal layer 46, it can be confirmed that the grooved wafer 40 is grooved unsuccessfully.

In an embodiment of the disclosure, the inspection method is employed in the grooving stage to not only inspect and determine whether the grooved wafer 40 is grooved successfully or grooved unsuccessfully but also process the groove 465 anew with the laser head 50 upon inspection and determination that the grooved wafer 40 is grooved unsuccessfully at a specific position. Therefore, the disclosure is effective in preventing dicing streets cracks and/or fractures which might otherwise develop as a result of uneven dicing stress caused by a defect of the groove 465 in the course of a subsequent dicing process.

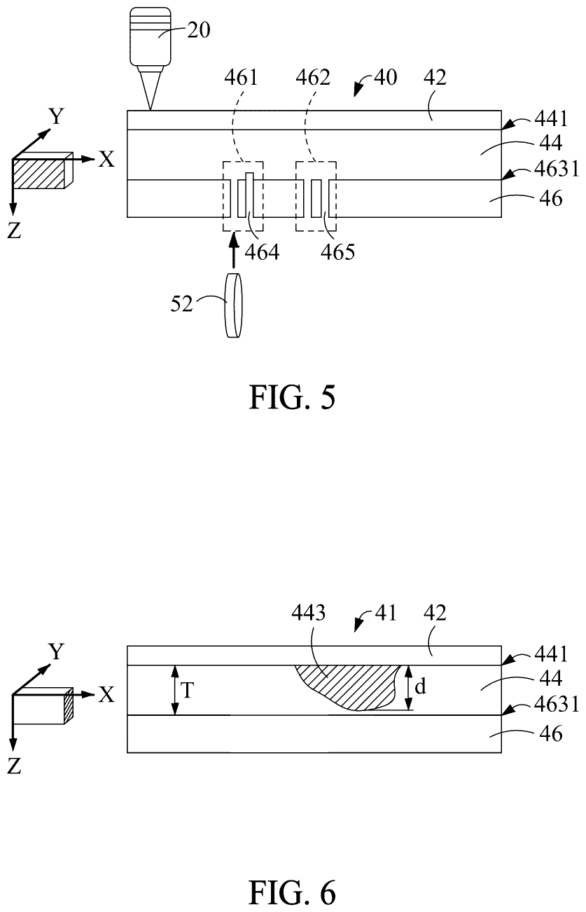

Referring to FIG. 5, there is shown a schematic view of how to perform a dicing process and the scanning process on the grooved wafer 40 according to an embodiment of the disclosure. As shown in FIG. 5, the optical scanning device 20 and a dicing cutting tool 52 are disposed on different sides of the grooved wafer 40 respectively. The optical scanning device 20 is disposed on one side of the adhesive film layer 42 of the grooved wafer 40, and the dicing cutting tool 52 is disposed on one side of the metal layer 46 of the grooved wafer 40. In the other embodiments, the optical scanning device 20 and the dicing cutting tool 52 are disposed on the same side of the grooved wafer 40. The optical scanning device 20 uses the metal layer 46 of the grooved wafer 40 as a light incident surface for the scanning process.

In the second dicing street region 462 shown in FIG. 5, the groove 465 and its neighboring another groove (not denoted by any reference numerals in the diagram) have already undergone a grooving procedure anew with the laser head 50, and the groove 465 has a depth that exceeds the border between the silicon layer 44 and the metal layer 46. Thus, it is confirmed that the second dicing street region 462 is grooved successfully.

Referring to FIG. 6, there is shown a partial structural schematic view of a diced wafer 41 according to an embodiment of the disclosure.

Upon completion of the grooving procedure, the grooved wafer 40 undergoes dicing with the dicing cutting tool 52 in Y-axis direction to directly reach the silicon layer 44 to almost become severed. When the dicing stage does not end up cutting the metal layer 46 fully, the dicing cutting tool 52 may generate a sidewall chipping defect 443 on the cross section. The inspection method in an embodiment of the disclosure is effective in not only inspecting the structure and position of the sidewall chipping defect 443 but also digitizing the depth of the sidewall chipping defect 443 between the silicon layer 44 and the metal layer 46.

Upon completion of the dicing process, the optical scanning device 20 performs the scanning process on the diced wafer 41, and the scanning process involves using the adhesive film layer 42 or the metal layer 46 of the diced wafer 41 as a light incident surface for the scanning process. The optical scanning device performs the scanning process on the diced wafer 41 in X-axis direction to obtain YZ section structure images corresponding in position to successive different positions on the diced wafer 41 and analyzes XZ section structure images beside the dicing streets of the diced die to inspect and determine whether the sidewall chipping defect 443 exists. In the other embodiments, the optical scanning device 20 performs the scanning process on the diced wafer 41 in Y-axis direction to obtain XZ section structure images corresponding in position to successive different positions on the diced wafer 41 and analyzes YZ section structure images beside the dicing streets of the diced die to inspect and determine whether the sidewall chipping defect 443 is present. As shown in FIG. 6, the sidewall chipping defect 443 exists in the silicon layer 44.

The optical image processing device 10 analyzes YZ or XZ section structure images at successive different positions beside the dicing streets of the diced die and defines positions corresponding in position to one or more dicing streets (not shown), the adhesive film layer 42, the silicon layer 44 and the metal layer 46.

The optical image processing device 10 calculates a maximum depth value according to a pixel length corresponding to maximum depth d of the sidewall chipping defect 443 and calculates a thickness value according to a pixel length corresponding to thickness T of the silicon layer 44. The optical image processing device 10 calculates the sidewall chipping defect depth percentage according to the maximum depth value and the thickness value. The sidewall chipping defect depth percentage=(maximum depth value÷thickness value)×100%. Therefore, data about the sidewall chipping defect depth percentage is used to confirm whether the sidewall chipping defect 443 comes into contact with the metal layer 46 and thereby determine whether the sidewall chipping defect 443 can cause damage to a circuit in the metal layer 46.

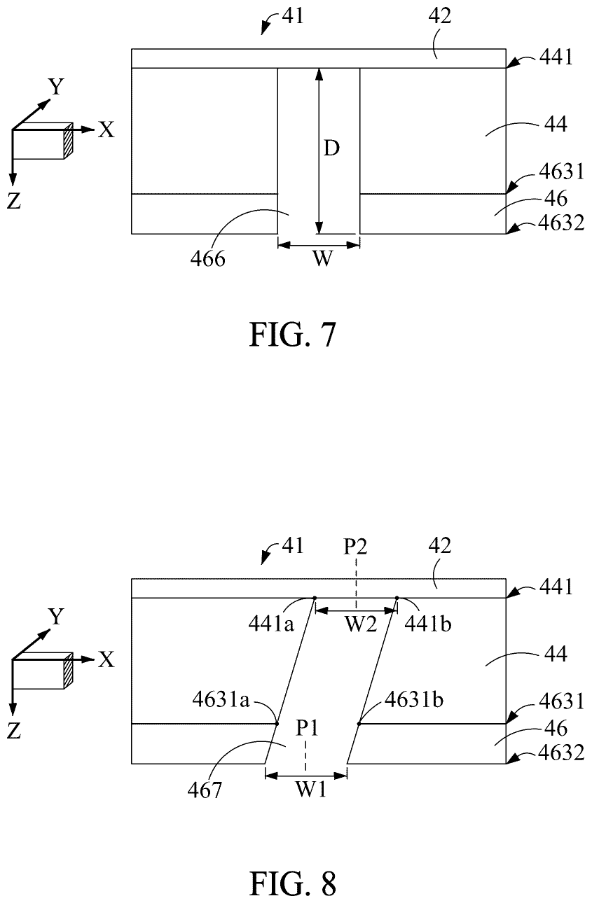

Referring to FIG. 7, there is shown another partial structural schematic view of the diced wafer 41 according to an embodiment of the disclosure. The optical image processing device 10 analyzes YZ section structure images at successive different positions and defines positions corresponding in position to one or more dicing streets 466, the adhesive film layer 42, the silicon layer 44 and the metal layer 46.

The optical image processing device 10 analyzes one or more dicing streets 466 and recognizes positions corresponding in position to dicing street width W and dicing street depth D.

The optical image processing device 10 calculates the dicing street aspect ratio according to the width value corresponding to dicing street width W and the depth value corresponding to dicing street depth D. In an embodiment of the disclosure, a pixel length corresponding to dicing street width W is analyzed to calculate a width value, and a pixel length corresponding to dicing street depth D is analyzed to calculate a depth value. The dicing street aspect ratio=width value÷depth value. Quantified data about the dicing street aspect ratio is provided to users to determine whether the dicing width and depth generated in the dicing process stage are sufficient or different from predetermined dicing width and depth, assessing a cutting tool condition and subsequent dicing quality. Therefore, it is feasible to replace the dicing cutting tool 52 or correct control parameters of the dicing cutting tool 52 to improve a dicing process and thereby enhance wafer yield.

Referring to FIG. 8, there is shown yet another partial structural schematic view of the diced wafer 41 according to an embodiment of the disclosure. The optical image processing device 10 analyzes YZ section structure images at successive different positions and defines positions corresponding in position to one or more dicing streets 467, the adhesive film layer 42, the silicon layer 44 and the metal layer 46. As shown in FIG. 8, the dicing streets 467 are of a skewed structure possibly because of the aging of the dicing cutting tool 52 or control parameter anomalies.

The optical image processing device 10 analyzes the dicing streets 467 and recognizes positions corresponding in position to dicing street width W and dicing street depth D. The optical image processing device 10 calculates first dicing street perpendicularity P1 according to a first width value W1 corresponding to dicing street width W. The first width value W1 corresponds to the dicing street width value exposed from the metal layer front side 4632. The optical image processing device 10 calculates second dicing street perpendicularity P2 according to a second width value W2 corresponding to dicing street width W. The second width value W2 corresponds to the dicing street width value exposed from the silicon layer front side 441. The optical image processing device 10 calculates a dicing street inclination according to first dicing street perpendicularity P1 and second dicing street perpendicularity P2.

In the other embodiments, the optical image processing device 10 obtains first end point XY coordinates 441a corresponding to left edges of top-surface dicing streets of the silicon layer 44 and second end point XY coordinates 441b corresponding to right edges of top-surface dicing streets of the silicon layer 44 according to XY section structure images of the silicon layer 44. Then, the optical image processing device 10 obtains third end point XY coordinates 4631a corresponding to left edges of bottom-surface dicing streets of the silicon layer 44 and fourth end point XY coordinates 4631b corresponding to right edges of bottom-surface dicing streets of the silicon layer 44 according to XY section structure images of the silicon layer 44. The optical image processing device 10 subtracts first end point XY coordinates 441a and third end point XY coordinates 4631a from each other to obtain left dicing street shift extent corresponding to the silicon layer and subtracts second end point XY coordinates 441b and fourth end point XY coordinates 4631b from each other to obtain right dicing street shift extent corresponding to the silicon layer.

Quantified data about dicing street perpendicularity and dicing street shift extent is provided to users to determine whether the dicing cutting tool 52 used in the dicing process stage is confronted with aging or control parameter anomalies. Therefore, it is feasible to replace the dicing cutting tool 52 or correct control parameters of the dicing cutting tool 52 to improve a dicing process and thereby enhance wafer yield.

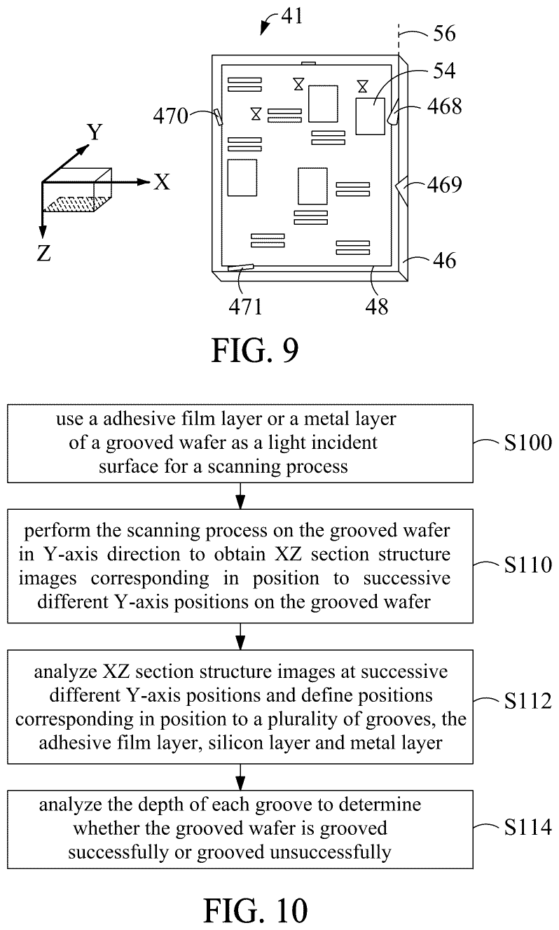

Referring to FIG. 9, there is shown a structural schematic view of a metal layer of the diced wafer 41 according to an embodiment of the disclosure. To facilitate illustration, the diced wafer 41 in FIG. 9 merely shows the structure of the metal layer 46.

The optical scanning device 20 performs the scanning process on the diced wafer 41 in X-axis and Y-axis directions and reconstructs wafer three-dimensional structure to obtain XY section structure images corresponding in position to successive different Z-axis positions on the diced wafer 41. Likewise, the optical scanning device 20 uses the adhesive film layer 42 of the diced wafer 41 as a light incident surface for the scanning process, but the disclosure is not limited thereto. In the other embodiments, the optical scanning device 20 uses the metal layer 46 of the diced wafer 41 as a light incident surface for the scanning process.

The optical image processing device 10 analyzes XY section structure images at successive different Z-axis positions, defines positions corresponding in position to a defective region 468, defective region 469, defective region 470, defective region 471 and chip edge56, and determines the position of a seal ring 48 according to XY section structure images of the metal layer 46.

The optical image processing device 10 analyzes whether the defective region 468, defective region 469, defective region 470 and defective region 471 exceed the seal ring 48 to determine whether the diced wafer 41 is a normal die or a defective die.

It is confirmed that the diced wafer 41 is a defective die when at least one of the defective region 468, defective region 469, defective region 470 and defective region 471 exceeds the seal ring 48. As shown in FIG. 9, all the defective region 468, defective region 470 and defective region 471 exceed the seal ring 48, and the defective region 468 even extends to a circuit component 54; therefore, it is confirmed that the diced wafer 41 is a defective die.

It is confirmed that the diced wafer 41 is a normal chip when none of the defective region 468, defective region 469, defective region 470 and defective region 471 exceeds the seal ring 48.

In the other embodiments, the optical image processing device 10 analyzes and determines whether at least one of the defective region 468, defective region 469, defective region 470 and defective region 471 is located within the seal ring 48 to determine whether the diced wafer 41 is a normal chip or a defective chip.

It is confirmed that the diced wafer 41 is a normal chip when at least one of the defective region 468, defective region 469, defective region 470 and defective region 471 is not located within the seal ring 48.

It is confirmed that the diced wafer 41 is a defective die when at least one of the defective region 468, defective region 469, defective region 470 and defective region 471 exceeds the seal ring 48 and is located within the seal ring 48. Therefore, the inspection method in an embodiment of the disclosure further involves inspecting whether a die in the diced wafer 41 is normal or defective, enhancing the diversity of inspection functions.

Referring to FIG. 10, there is shown a schematic view of a process flow of an inspection method of a wafer dicing process (grooved stage) according to an embodiment of the disclosure. In an embodiment of the disclosure, the inspection method of a wafer dicing process is adapted to perform a scanning process on the grooved wafer 40 with a light beam used by the optical scanning device 20 and employ the optical image processing device 10 to perform an image analysis procedure and a data calculation procedure on section structure images obtained by the scanning process.

Step S100: the optical scanning device 20 uses the adhesive film layer 42 or the metal layer 46 of the grooved wafer 40 as a light incident surface for the scanning process.

Step S110: the optical scanning device 20 performs the scanning process on the grooved wafer 40 in Y-axis direction to obtain XZ section structure images corresponding in position to successive different Y-axis positions on the grooved wafer 40.

Step S112: the optical image processing device 10 analyzes XZ section structure images at successive different Y-axis positions and defines positions corresponding in position to a plurality of grooves, the adhesive film layer 42, the silicon layer 44 and the metal layer 46.

Step S114: the optical image processing device 10 analyzes a depth of each of the grooves to determine whether the grooved wafer 40 is grooved successfully or grooved unsuccessfully, confirming that the grooved wafer 40 is grooved successfully when the depth of each of the grooves exceeds the border between the silicon layer 44 and the metal layer 46, and confirming that the grooved wafer 40 is grooved unsuccessfully when the depth of each of the grooves is equal to or less than the border between the silicon layer 44 and the metal layer 46.

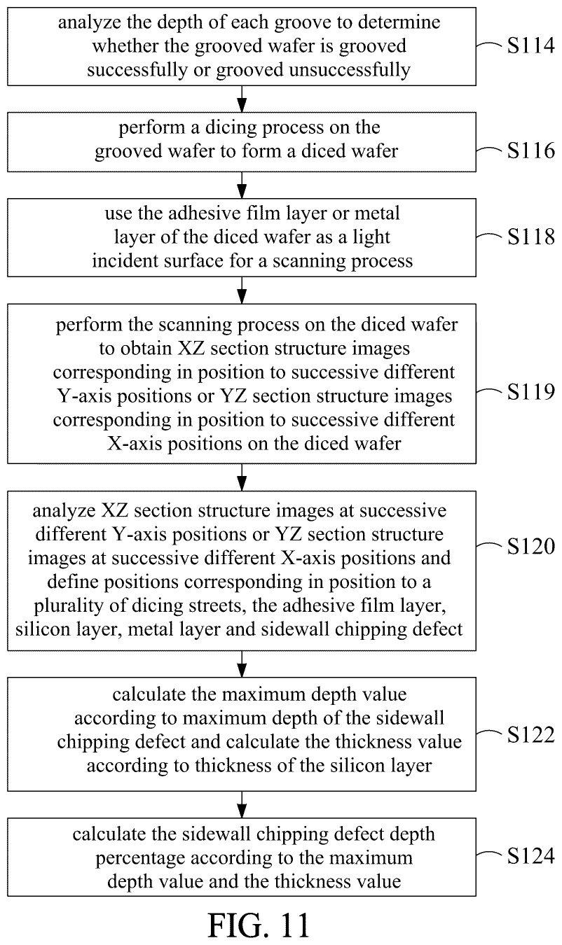

Referring to FIG. 11, there is shown a schematic view of a process flow of the inspection method of a wafer dicing process (diced stage) according to another embodiment of the disclosure. Step S100, step S110 and step S112 in FIG. 11 are the same as their counterparts in FIG. 10 respectively and thus are, for the sake of brevity, not reiterated. However, FIG. 11 omits the description of step S100, step S110 and step S112.

Step S114: the optical image processing device 10 analyzes and determines whether the depth of each of the grooves exceeds or is equal to the border between the silicon layer 44 and the metal layer 46 to determine whether the grooved wafer 40 is grooved successfully or grooved unsuccessfully.

Step S116: perform a dicing process on the grooved wafer 40 to form the diced wafer 41.

Step S118: the optical image processing device 10 uses the adhesive film layer 42 or the metal layer 46 of the diced wafer 41 as a light incident surface for a scanning process.

Step S119: the optical image processing device 10 performs the scanning process on the diced wafer 41 to obtain XZ section structure images corresponding in position to successive different Y-axis positions or YZ section structure images corresponding in position to successive different X-axis positions on the diced wafer 41.

Step S120: the optical image processing device 10 analyzes XZ section structure images at successive different Y-axis positions or YZ section structure images at successive different X-axis positions and defines positions corresponding in position to a plurality of dicing streets, the adhesive film layer 42, the silicon layer 44, the metal layer 46 and the sidewall chipping defect.

Step S122: the optical image processing device 10 calculates the maximum depth value according to maximum depth d of the sidewall chipping defect and calculates the thickness value according to thickness T of the silicon layer 44. In the other embodiments, the optical image processing device 10 calculates the maximum depth value according to a pixel length corresponding to maximum depth d of the sidewall chipping defect and calculates the thickness value according to a pixel length corresponding to thickness T of the silicon layer 44.

Step S124: the optical image processing device 10 calculates the sidewall chipping defect depth percentage according to the maximum depth value and the thickness value. The sidewall chipping defect depth percentage=(maximum depth value÷thickness value)×100%.

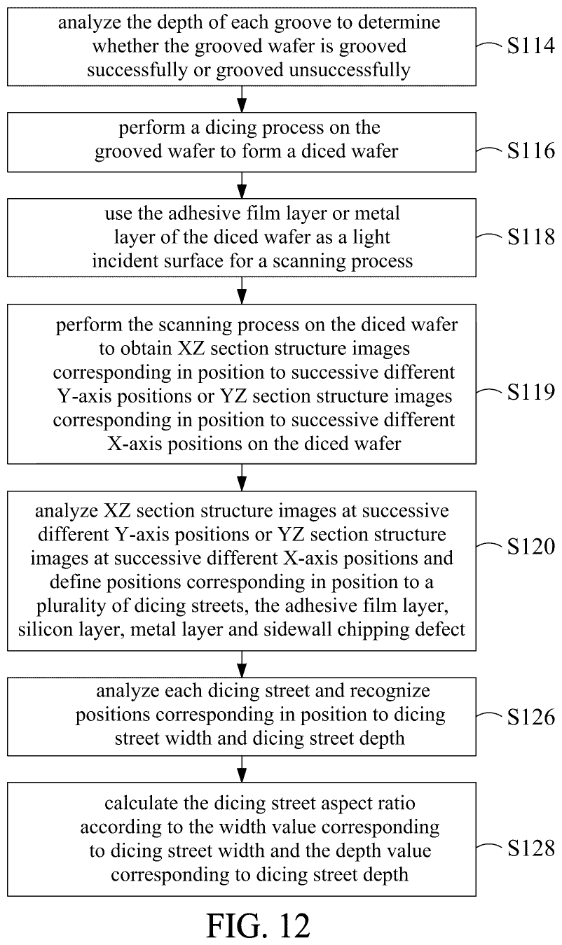

Referring to FIG. 12, there is shown a schematic view of a process flow of the inspection method of a wafer dicing process according to yet another embodiment of the disclosure. Step S114, step S116, step S118, step S119 and step S120 in FIG. 12 are the same as their counterparts in FIG. 11 respectively and thus are, for the sake of brevity, not reiterated. However, FIG. 12 omits the description of step S100, step S110 and step S112.

Step S126: the optical image processing device 10 analyzes each of the dicing streets and recognizes positions corresponding in position to dicing street width W and dicing street depth D.

Step S128: the optical image processing device 10 calculates the dicing street aspect ratio according to the width value corresponding to dicing street width W and the depth value corresponding to dicing street depth D.

$$\begin{matrix}the dicing street \\ aspect ratio = \frac{depth value}{width value} .\end{matrix}$$

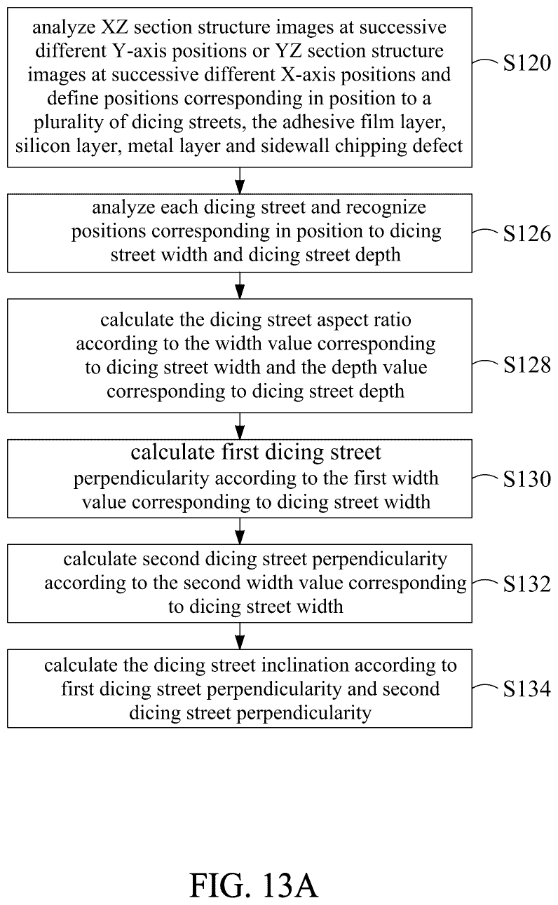

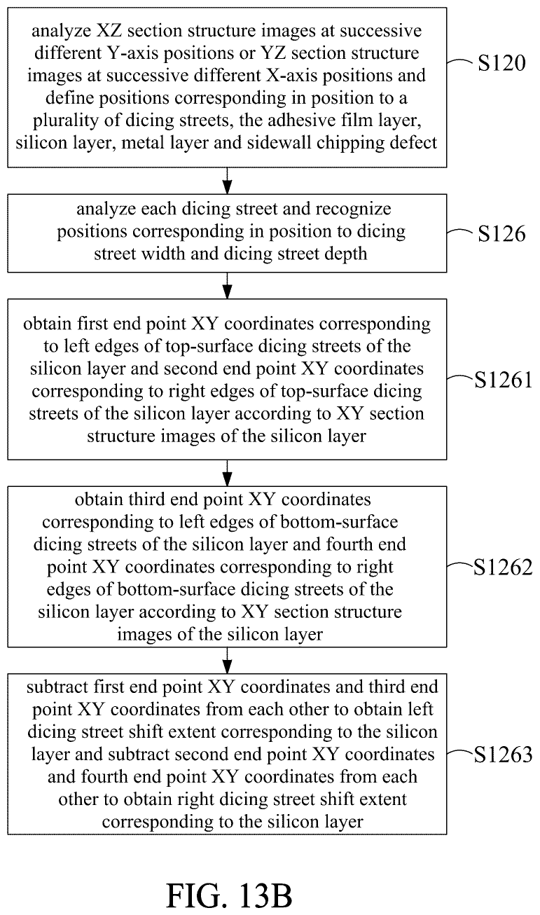

Referring to FIG. 13A, there is shown a schematic view of a process flow of the inspection method of a wafer dicing process according to still yet another embodiment of the disclosure. Step S114, step S116, step S118, step S119 and step S120 in FIG. 13A are the same as their counterparts in FIG. 11 respectively and thus are, for the sake of brevity, not reiterated. However, FIG. 13A omits the description of step S100, step S110, step S112, step S114, step S116, step S118 and step S119.

Step S130: the optical image processing device 10 calculates first dicing street perpendicularity P1 according to the first width value W1 corresponding to dicing street width W.

Step S132: the optical image processing device 10 calculates second dicing street perpendicularity P2 according to the second width value W2 corresponding to dicing street width W.

Step S134: the optical image processing device 10 calculates the dicing street inclination according to first dicing street perpendicularity P1 and second dicing street perpendicularity P2.

Referring to FIG. 13B, there is shown a schematic view of a process flow of the inspection method of a wafer dicing process according to still yet another embodiment of the disclosure. Step S114, step S116, step S118, step S119 and step S120 in FIG. 13B are the same as their counterparts in FIG. 11 respectively and thus are, for the sake of brevity, not reiterated. However, FIG. 13B omits the description of step S100, step S110, step S112, step S114, step S116, step S118 and step S119.

Step S126: the optical image processing device 10 analyzes each of the dicing streets and recognizes positions corresponding in position to dicing street width W and dicing street depth D.

Step S1261: the optical image processing device 10 obtains first end point XY coordinates 441a corresponding to left edges of top-surface dicing streets of the silicon layer 44 and second end point XY coordinates 441b corresponding to right edges of top-surface dicing streets of the silicon layer 44 according to XY section structure images of the silicon layer 44.

Step S1262: the optical image processing device 10 obtains third end point XY coordinates 4631a corresponding to left edges of bottom-surface dicing streets of the silicon layer 44 and fourth end point XY coordinates 4631b corresponding to right edges of bottom-surface dicing streets of the silicon layer 44 according to XY section structure images of the silicon layer 44.

Step S1263: the optical image processing device 10 subtracts first end point XY coordinates 441a and third end point XY coordinates 4631a from each other to obtain left dicing street shift extent corresponding to the silicon layer 44 and subtracts second end point XY coordinates 441b and fourth end point XY coordinates 4631b from each other to obtain right dicing street shift extent corresponding to the silicon layer 44.

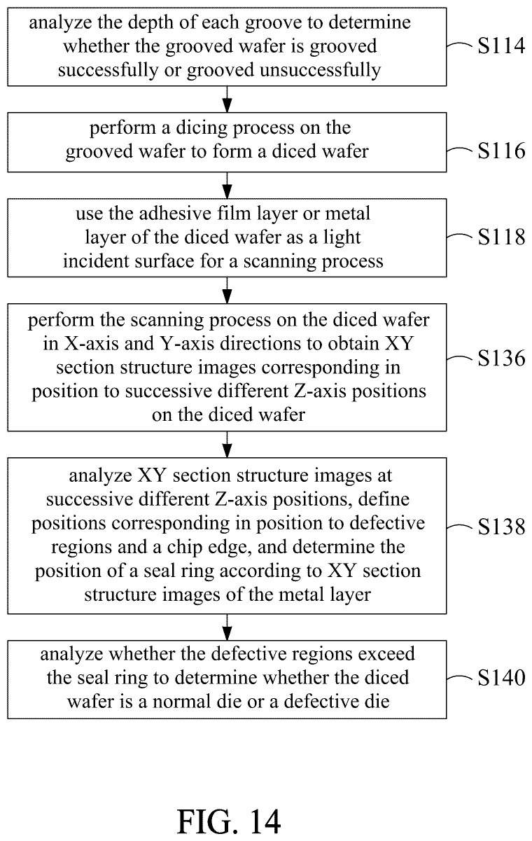

Referring to FIG. 14, there is shown a schematic view of a process flow of the inspection method of a wafer dicing process according to still yet another embodiment of the disclosure. Step S114, step S116 and step S118 in FIG. 14 are the same as their counterparts in FIG. 11 respectively and thus are, for the sake of brevity, not reiterated. However, FIG. 14 omits the description of step S100, step S110 and step S112.

Step S136: perform the scanning process on the diced wafer 41 in X-axis and Y-axis directions to obtain XY section structure images corresponding in position to successive different Z-axis positions on the diced wafer 41.

Step S138: the optical image processing device 10 analyzes XY section structure images at successive different Z-axis positions, defines positions corresponding in position to the defective region 468, defective region 469, defective region 470, defective region 471 and chip edge, and determines the position of the seal ring 48 according to XY section structure images of the metal layer 46. Furthermore, in this embodiment, the positions and numbers of the defective region 468, defective region 469, defective region 470 and defective region 471 are specified herein for exemplary purposes, but the disclosure is not limited thereto.

Step S140: the optical image processing device 10 analyzes whether the defective region 468, defective region 469, defective region 470 and defective region 471 exceed the seal ring 48 to determine whether the diced wafer 41 is a normal die or a defective die, confirming that the diced wafer 41 is a defective die when at least one of the defective region 468, defective region 469, defective region 470 and defective region 471 exceeds the seal ring 48, and confirming that the diced wafer 41 is a normal die when none of the defective region 468, defective region 469, defective region 470 and defective region 471 exceeds the seal ring 48.

In the other embodiments, the optical image processing device 10 analyzes whether at least one of the defective region 468, defective region 469, defective region 470 and defective region 471 is located within the seal ring 48 to determine whether the diced wafer 41 is a normal die or a defective die, confirming that the diced wafer 41 is a defective die when at least one of the defective region 468, defective region 469, defective region 470 and defective region 471 is located within the seal ring 48, and confirming that the diced wafer 41 is a normal die when none of the defective region 468, defective region 469, defective region 470 and defective region 471 is located within the seal ring 48.

In conclusion, an inspection method of a wafer dicing process according to the disclosure is adapted to scan a grooved wafer or diced wafer with a light beam used by an optical scanning device to obtain optical signals and then perform conversion on the optical signals with an optical images processing device to display different section structure images corresponding to the grooved wafer or diced wafer to facilitate the observation of internal structures of dicing streets and thereby confirm the processing quality of the dicing streets.

The present invention is described by way of the preferred embodiments above. A person skilled in the art should understand that, these embodiments are merely for describing the present invention and are not to be construed as limitations to the scope of the present invention. It should be noted that all equivalent changes, replacements and substitutions made to the embodiments are to be encompassed within the scope of the present invention. Therefore, the scope of protection of the present invention should be accorded with the broadest interpretation of the appended claims.

What is claimed is:

1. An inspection method of a wafer dicing process, adapted to perform a scanning process on a grooved wafer with a light beam used by an optical scanning device, the inspection method comprising the steps of:
using an adhesive film layer or metal layer of the grooved wafer as a light incident surface for the scanning process;
performing the scanning process on the grooved wafer in a Y-axis direction to obtain XZ section structure images corresponding in position to successive different Y-axis positions on the grooved wafer;
analyzing the XZ section structure images at the successive different Y-axis positions and defining positions corresponding in position to a plurality of grooves, the adhesive film layer, a silicon layer and the metal layer; and
analyzing a depth of each of the grooves to determine whether the grooved wafer is grooved successfully or grooved unsuccessfully.

2. The inspection method of a wafer dicing process according to claim 1, wherein a determination that the depth of each of the grooves exceeds a border between the silicon layer and the metal layer causes a confirmation that the grooved wafer is grooved successfully, and a determination that the depth of each of the grooves is equal to or less than the border between the silicon layer and the metal layer causes a confirmation that the grooved wafer is grooved unsuccessfully.

3. The inspection method of a wafer dicing process according to claim 1, further comprising, after the step of analyzing a depth of each of the grooves to determine whether the grooved wafer is grooved successfully or grooved unsuccessfully, the steps of:
performing a dicing process on the grooved wafer to form a diced wafer;
using the adhesive film layer or the metal layer of the diced wafer as a light incident surface for the scanning process;
performing the scanning process on the diced wafer to obtain XZ section structure images corresponding in position to successive different Y-axis positions or YZ section structure images corresponding in position to successive different X-axis positions on the diced wafer;
analyzing the XZ section structure images at the successive different Y-axis positions or the YZ section structure images at the successive different X-axis positions and defining positions corresponding in position to a plurality of dicing streets, the adhesive film layer, the silicon layer, the metal layer, and a sidewall chipping defect;
calculating a maximum depth value according to a maximum depth of the sidewall chipping defect, and calculating a thickness value according to a thickness of the silicon layer; and
calculating a sidewall chipping defect depth percentage according to the maximum depth value and the thickness value.

4. The inspection method of a wafer dicing process according to claim 3, wherein the maximum depth value and the thickness value are calculated according to a pixel length corresponding to the maximum depth and a pixel length corresponding to the thickness.

5. The inspection method of a wafer dicing process according to claim 3, wherein
$$the sidewall chipping defect depth percentage = \frac{maximum depth value}{thickness value} \times 100 \% .$$

6. The inspection method of a wafer dicing process according to claim 3, further comprising, after the step of analyzing the YZ section structure images at the successive different X-axis positions and defining positions corresponding in position to a plurality of dicing streets, the adhesive film layer, the silicon layer, the metal layer, and a sidewall chipping defect, the steps of:
analyzing each of the dicing streets and recognizing positions corresponding in position to a dicing street width and a dicing street depth; and
calculating a dicing street aspect ratio according to a width value corresponding to the dicing street width and a depth value corresponding to the dicing street depth.

7. The inspection method of a wafer dicing process according to claim 6, wherein
$$the dicing street aspect ratio = \frac{depth value}{width value} .$$

8. The inspection method of a wafer dicing process according to claim 6, further comprising, after the step of analyzing each of the dicing streets and recognizing positions corresponding in position to a dicing street width and a dicing street depth, the steps of:
calculating a first dicing street perpendicularity according to a first width value corresponding to the dicing street width;
calculating a second dicing street perpendicularity according to a second width value corresponding to the dicing street width; and
calculating a dicing street inclination according to the first dicing street perpendicularity and the second dicing street perpendicularity.

9. The inspection method of a wafer dicing process according to claim 6, further comprising, after the step of analyzing each of the dicing streets and recognizing positions corresponding in position to a dicing street width and a dicing street depth, the steps of:
obtaining first end point XY coordinates corresponding to left edges of top-surface dicing streets of the silicon layer and second end point XY coordinates corresponding to right edges of top-surface dicing streets of the silicon layer according to XY section structure images of the silicon layer;
obtaining third end point XY coordinates corresponding to left edges of bottom-surface dicing streets of the silicon layer and fourth end point XY coordinates corresponding to right edges of bottom-surface dicing streets of the silicon layer according to XY section structure images of the silicon layer; and
subtracting the first end point XY coordinates and the third end point XY coordinates from each other to obtain left dicing street shift extent corresponding to the silicon layer, and subtracting the second end point XY coordinates and the fourth end point XY coordinates from each other to obtain right dicing street shift extent corresponding to the silicon layer.

10. The inspection method of a wafer dicing process according to claim 3, further comprising, after the step of using the adhesive film layer or the metal layer of the diced wafer as a light incident surface for the scanning process, the steps of:
performing the scanning process on the diced wafer in X-axis and Y-axis directions to obtain XY section structure images corresponding in position to successive different Z-axis positions on the diced wafer;
analyzing XY section structure images at successive different Z-axis positions, defining positions corresponding in position to a defective region and a chip edge, and determining a position of a seal ring according to XY section structure images of the metal layer; and
analyzing whether the defective region exceeds the seal ring to determine whether the diced wafer is a normal die or a defective die.

11. The inspection method of a wafer dicing process according to claim 10, wherein a determination that the defective region exceeds the seal ring causes a confirmation that the diced wafer is a defective die, and a determination that the defective region does not exceed the seal ring causes a confirmation that the diced wafer is a normal die.

12. The inspection method of a wafer dicing process according to claim 10, further comprising, after the step of analyzing XY section structure images at successive different Z-axis positions and defining positions corresponding in position to a defective region and a chip edge, the step of analyzing whether the defective region is located within the seal ring to determine whether the diced wafer is a normal die or a defective dic.
